(19) United States
(12) Patent Application Publication
(10) Pub. No.: US 2010/0219341 A1
(43) Pub. Date: Sep. 2, 2010

(54) POWER AND ENERGY METER FOR MEASURING ELECTROMAGNETIC RADIATION

(75) Inventors: JAMES D. PARSONS, Reno, NV (US); Andrew D. Devey, Reno, NV (US)

Correspondence Address: KOPPEL, PATRICK, HEYBL & DAWSON, 2815 Townsgate Road, SUITE 215, Westlake Village, CA, 91361-5827, US

(73) Assignee: HEETRONIX

(21) Appl. No.: 12/546,080

(22) Filed: Aug. 24, 2009

Related U.S. Application Data
(60) Provisional application No. 61/092,295, filed on Aug. 27, 2008.

(51) Int. Cl. G01J 5/00; H01L 31/024; G01K 13/00

(52) U.S. Cl. 250/338.3; 250/238; 374/141; 374/E13.001

(57) ABSTRACT

A power and energy (PE) meter includes a sensor head comprising a sensor which absorbs EM radiation that impinges on it, and a heat sink with which the sensor is in thermal contact. The heat sink includes a through-hole behind the sensor which allows at least some of the EM radiation which is not absorbed by the sensor to pass through the heat sink without being absorbed. A means of applying mechanical pressure is preferably employed to hold the sensor in thermal contact with the heat sink. A capture head and shroud may be mounted behind and physically separate from the sensor head, and arranged to absorb at least some of the radiation which is not absorbed by the sensor head.

### RELATED APPLICATIONS

This application claims the benefit of provisional patent application No. 61/092,295 to James D. Parsons and Andrew D. Devey, filed Aug. 27, 2008.

### BACKGROUND OF THE INVENTION

1. Field of the Invention

This invention relates generally to power and energy (PE) meters, and more particularly to PE meters designed to measure electromagnetic radiation.

2. Description of the Related Art

A power and energy (PE) meter is a device designed to measure power and/or energy being conveyed, either through free space or via some sort of conductor. For example, a PE meter could be designed to measure directed electromagnetic (EM) radiation traveling through air or free space. These types of PE meters are usually comprised of a single or multi-component sensor, a heat sink, and electrical and/or thermal connections between the sensor and a display instrument.

Sensors used to measure directed EM radiation include, but are not limited to: thermopiles, bolometers, photoconductors, photodiodes, pyroelectrics and calorimeters. Some sensors operate by absorbing part or all of the EM radiation entering a sensor, such that the sensor temperature increases in a manner proportional to the amount of radiation absorbed. Sensors which use temperature change to indicate the amount of EM radiation absorbed must be calibrated when housed in the heat sink, since the power associated with a given change in temperature is dependent on the sensor/heat sink combination—commonly referred to as a “sensor head”—and on the cooling of the sensor head.

Heat sinks are usually metal, and conduct heat away from the sensors with which they are in contact via conduction, convection, and by thermal radiation. The rate at which heat is transferred away from a sensor by the heat sink depends upon the thermal resistance between the sensor and heat sink surface, and on how fast heat can be removed from the heat sink. Heat sinks are cooled by natural convection, forced air (through or over the heat sink surface), or by liquid cooling (through or over the heat sink surface). A heat sink also provides support for electrical or thermal I/O.

Front and side views of a conventional PE meter sensor head are shown in FIGS. 1a and 1b, respectively. An EM radiation sensor 10 is mounted against one side of a heat sink 12, such that EM radiation 14 entering the sensor on its other side—if not completely absorbed by the sensor—will enter and be absorbed by the heat sink itself. This mounting arrangement has several problems. For example, if a sensor is not thick enough to absorb all of the incoming EM radiation, then some or all of the un-absorbed radiation will be absorbed by the heat sink, thereby increasing its temperature beyond that which would be achieved due to the heating of the sensor alone. This makes sensor head calibration far more difficult, as the heat sink's temperature increase will vary with the amount of heat transfer that occurs—via thermal conduction/convection/radiation—between the sensor and the heat sink, and with the amount of EM radiation that is absorbed by the heat sink.

Another problem is that, except for very low amounts of EM radiation, the absorbing part of the sensor must be bonded, brazed or soldered to the heat sink with thermally conductive materials to maximize heat transfer away from the absorbing part of the sensor, to prevent the sensor from overheating or becoming saturated. In addition, the maximum EM radiation that may be measured by the sensor head is limited by the requirement that all of the radiation entering the sensor be absorbed by the sensor head.

### SUMMARY OF THE INVENTION

A PE meter designed to measure electromagnetic radiation is presented which addresses each of the problems noted above.

The present PE meter includes a sensor head comprising a sensor which absorbs EM radiation that impinges on it, and a heat sink with which the sensor is in thermal contact. The heat sink includes a through-hole located behind the sensor which allows at least some of the EM radiation which is not absorbed by the sensor to pass through the heat sink without being absorbed. The EM radiation may be, for example, directed EM radiation such as that produced by a laser, or EM radiation such as that produced by one or more light-emitting diodes (LEDs).

The present PE meter preferably also includes a means of applying mechanical pressure—such as a spring mechanism—which holds the sensor in thermal contact with the heat sink, thereby avoiding the need to bond, braze or solder the sensor to the heat sink.

A “capture head” is preferably mounted behind and physically separate from the sensor head, and is arranged to absorb at least some of the EM radiation which is not absorbed by the sensor and which passes through the heat sink without being absorbed. A “shroud” might also be positioned between the capture head and sensor head, either attached to the perimeter of the capture head or self-standing.

These and other features, aspects, and advantages of the present invention will become better understood with reference to the following drawings, description, and claims.

### BRIEF DESCRIPTION OF THE DRAWINGS

FIGS. 1a and 1b are front and side views, respectively, of a conventional PE meter sensor head.

FIGS. 2a and 2b are front and side views, respectively, of one possible embodiment of a PE meter sensor head in accordance with the present invention.

FIGS. 3a and 3b are front and side views, respectively, of another possible embodiment of a PE meter sensor head in accordance with the present invention.

FIG. 4 is a front view of a PE meter sensor head in accordance with the present invention, showing one possible means of holding the sensor to the heat sink.

FIG. 5 is a sectional view of a PE meter sensor head in accordance with the present invention, showing one possible spring-loading mechanism.

FIG. 6 is a front view of a capture head and shroud as might be used with a PE meter in accordance with the present invention.

FIG. 7 is a sectional view of a capture head and shroud as might be used with a PE meter in accordance with the present invention.

FIG. 8 is a perspective view of a system which includes a source of directed EM radiation, a sensor head and a capture head and shroud as might be used with a PE meter in accordance with the present invention.

FIG. 9 is a diagram of a sensor with a roughened surface as might be used with a PE meter sensor head in accordance with the present invention.

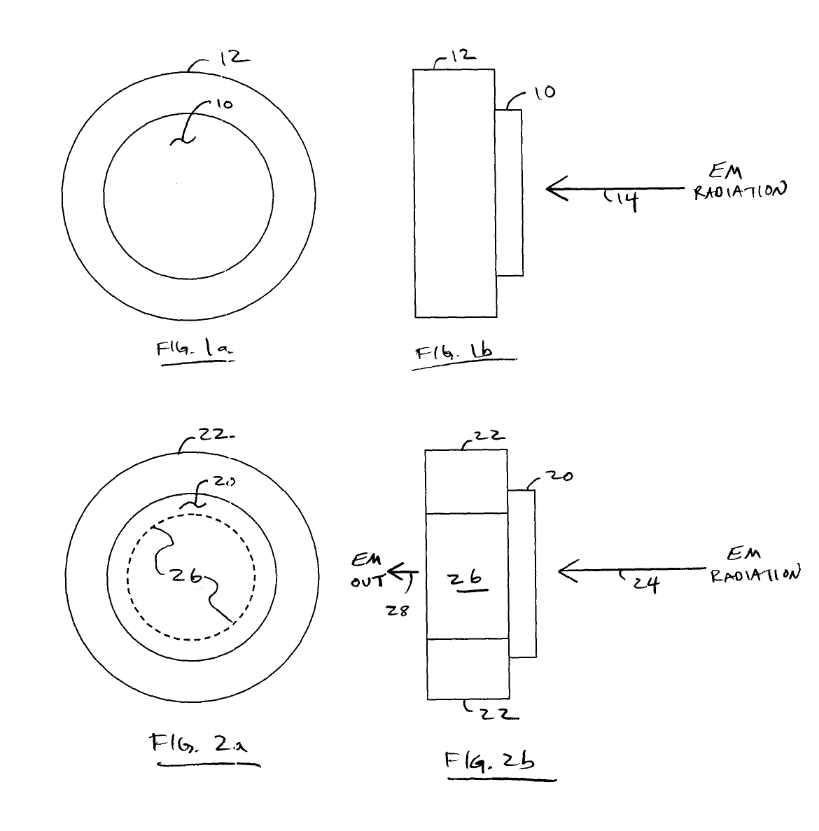

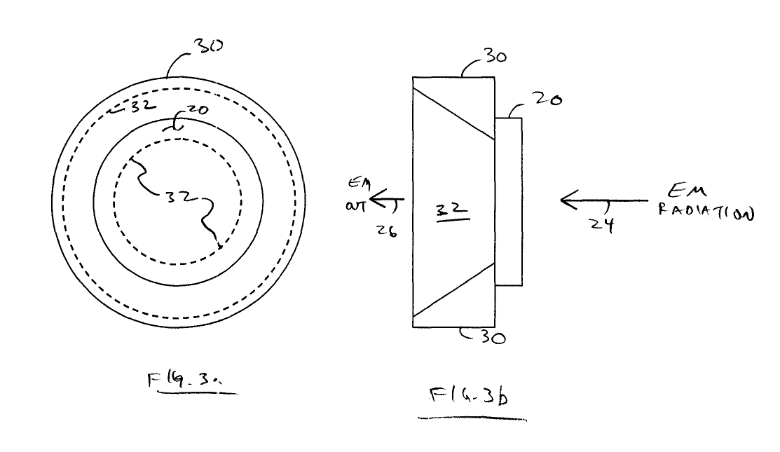

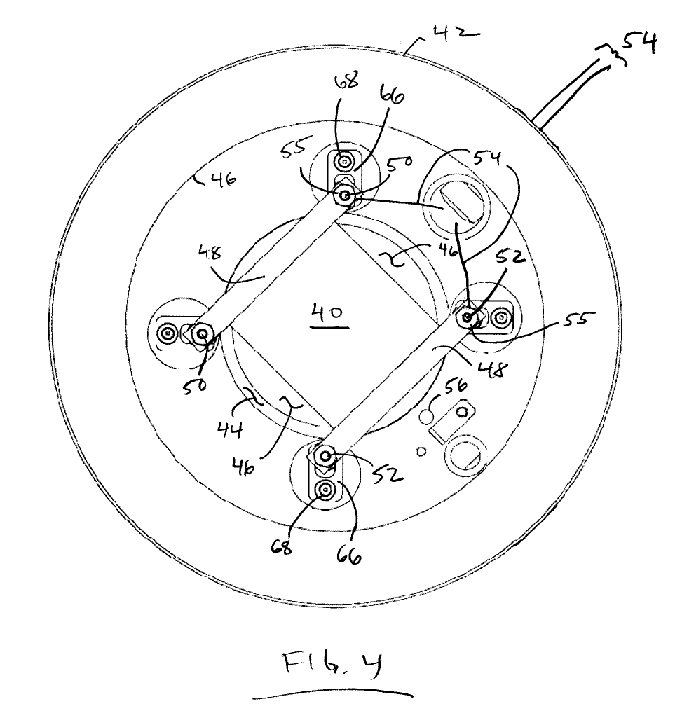

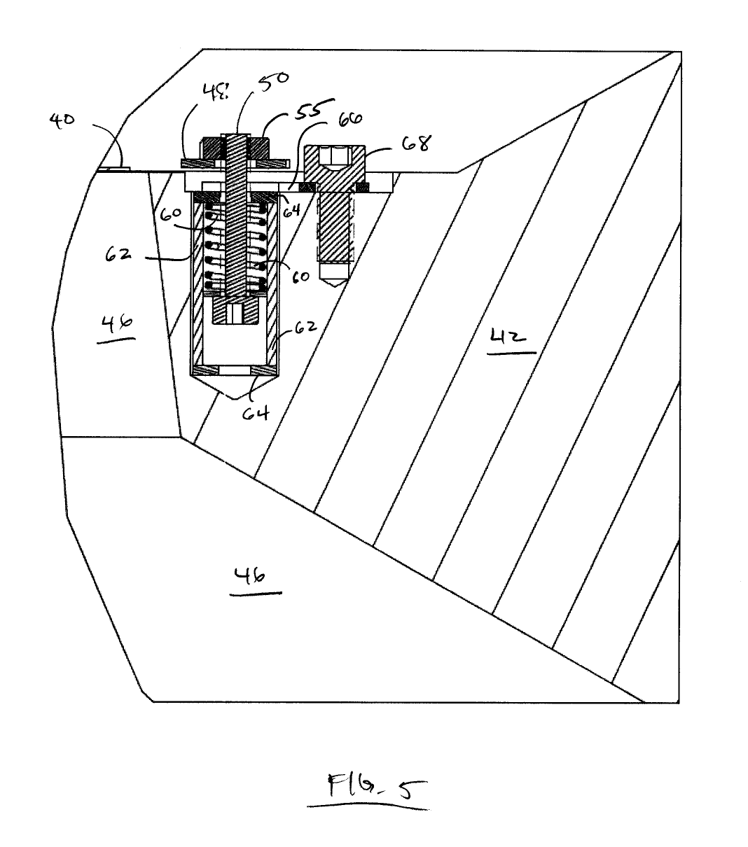

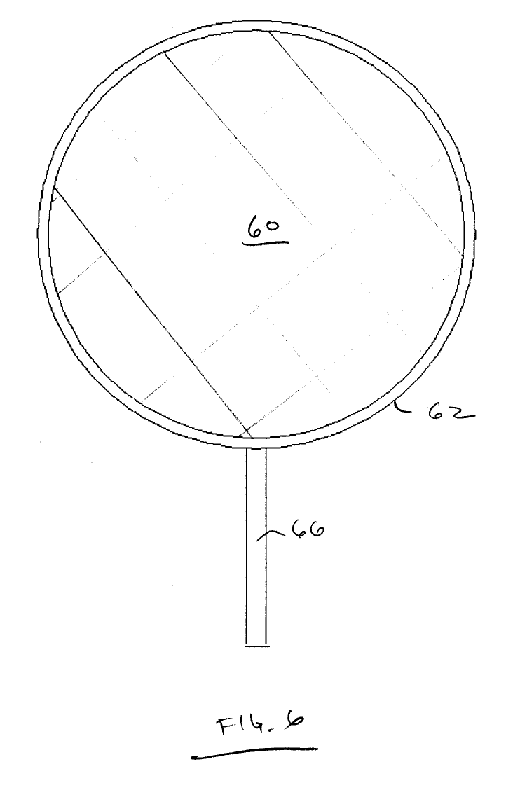

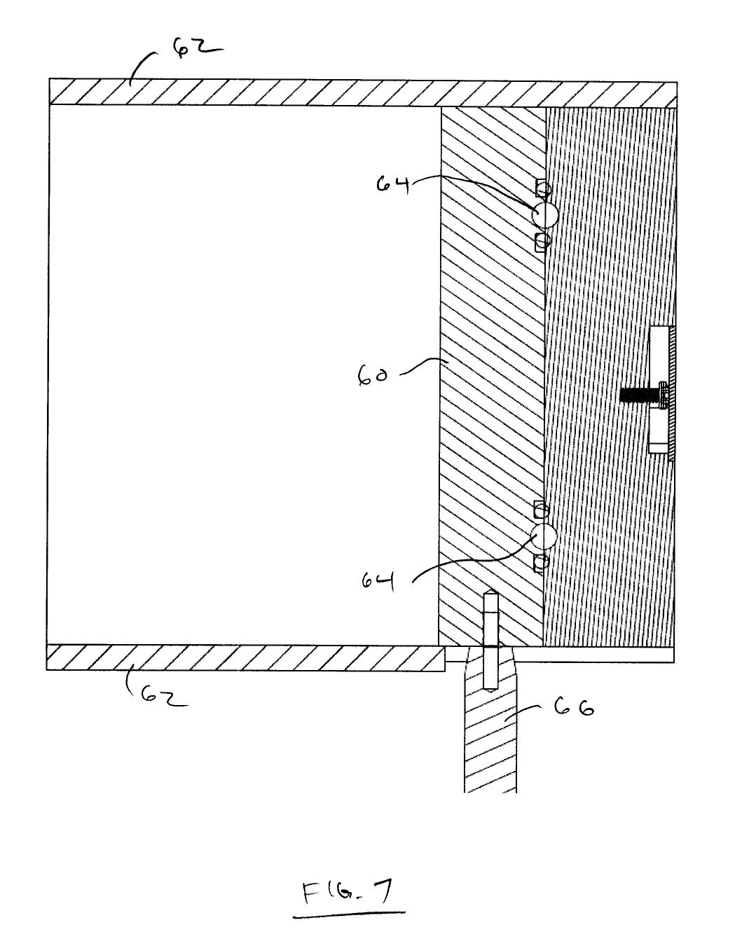

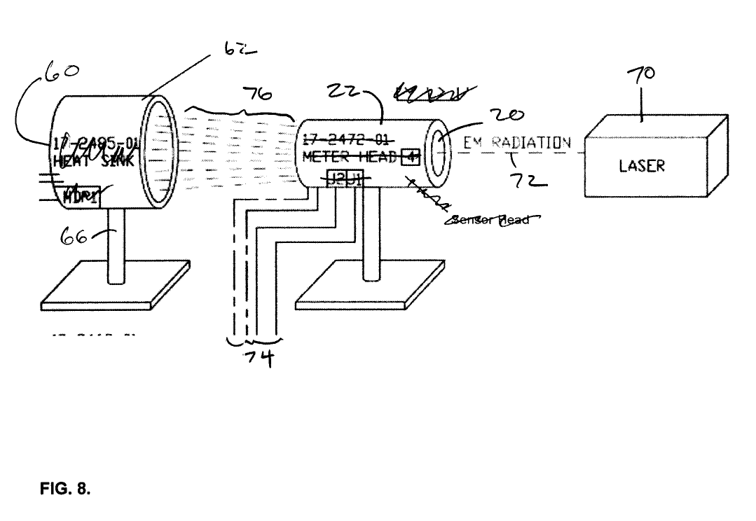

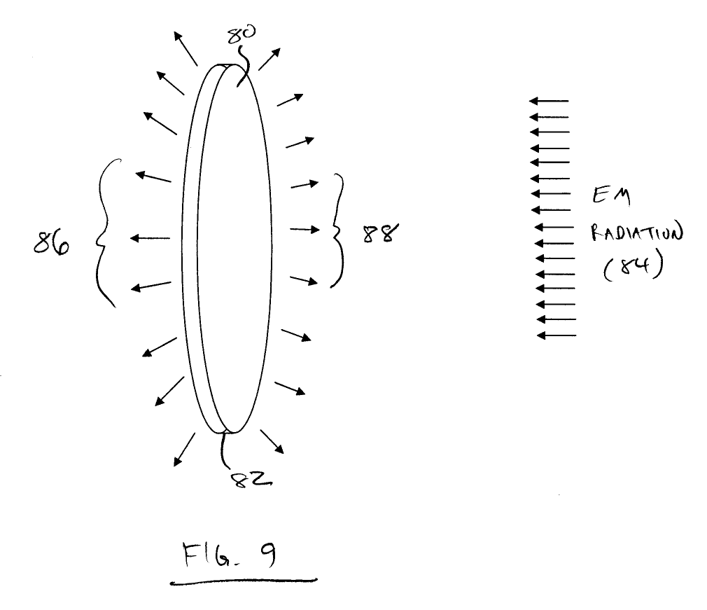

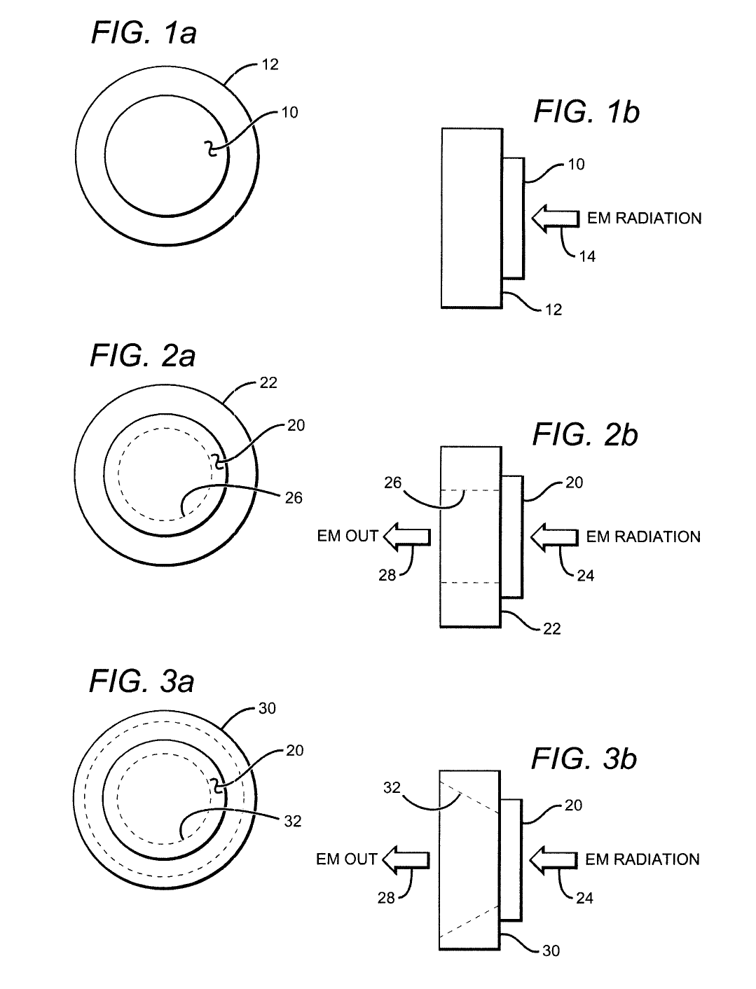

### DETAILED DESCRIPTION OF THE INVENTION

Front and side views showing one aspect of a PE meter sensor head in accordance with the present invention are shown in FIGS. 2a and 2b, respectively. The sensor head includes an EM radiation sensor 20 which is in thermal contact with a heat sink and is arranged to absorb EM radiation 24 impinging on the sensor. The heat sink includes a through-hole 26 located behind sensor 20, which allows at least some of the EM radiation 24 which is not absorbed by the sensor to pass through heat sink 22 without being absorbed. Note that, though only one sensor is depicted in the figures, EM radiation sensor 20 may actually consist of more than one sensor.

The outer periphery of sensor 20 contacts the inner periphery of the through-hole. Providing a through-hole 26 behind the sensor in this manner enables the use of thinner sensors which do not absorb all of the EM radiation that enters them, because the heat sink 22 does not absorb—and is therefore not heated by—the exiting flux (28). Note that, though sensor 20 and heat sink 22 are shown as round in the figures, each can have any shape that can be fabricated—as long as there is a hole in the heat sink behind the sensor such that at least some of the EM radiation 24 which is not absorbed by the sensor passes through heat sink 22 without being absorbed.

The present PE meter is designed to measure EM radiation, such as that generated by one or more LEDs, or directed EM radiation, such as that generated by a laser. For example, the PE meter could be arranged to measure the power or the energy profile/distribution present within a cross-sectional area of a directed EM radiation beam.

The PE meter is not limited to any specific type of sensor. One type of sensor suitable for measuring EM radiation comprises an absorber which is heated by EM radiation impinging on it, and a temperature measurement device arranged to produce an output which varies with the temperature of the absorber. The temperature measurement device might be, for example, a calorimeter, pyroelectric, thermopile, bolometer, thermistor, resistance temperature device (RTD) or thermocouple. The absorber is typically a solid material, which may or may not be coated with a thin or thick film that absorbs EM radiation. Examples of sensors that may be suitable for use with the present meter are described, for example, in U.S. Pat. Nos. 6,239,432, 6,576,972, 6,649,994, 6,713,762, and 7,176,461, all of which are assigned to the present assignee.

Another type of sensor suitable for measuring EM radiation is arranged to produce an electrical output signal which varies with the amount of EM radiation impinging on the sensor. Here, the sensor could comprise, for example, one or more photodiodes or photoconductors.

As depicted in the front and side views shown in FIGS. 3a and 3b, respectively, the sensor head heat sink (30) can have a chamfered through-hole (32). This helps avoid absorption of EM radiation (26) that has passed completely through sensor 20. The sensor head heat sink preferably comprises metal; aluminum, copper or steel are suitable materials.

As discussed in more detail below, one or both surfaces of sensor 20 may be roughened, which acts to scatter reflected and transmitted radiation. Much of the reflected and transmitted radiation impinging on the sensor does not arrive from a perpendicular direction. This non-perpendicular radiation can be absorbed by the heat sink component of the sensor head, causing the sensor head to get hotter due to radiation absorbed by the heat sink directly. Using a chamfered heat sink hole (32) as shown in FIGS. 3a and 3b, and by using mirrored surfaces on the inside surfaces of heat sink 30, direct absorption of reflected and transmitted radiation by the heat sink can be reduced or eliminated.

The sensor head preferably employs mechanical pressure to hold the sensor(s) in thermal contact with the heat sink. This avoids the need to bond, braze or solder the sensor to the heat sink. Since the heat sink through-hole eliminates the need for the sensor to absorb all the incoming EM radiation, holding the sensor to the heat sink by mechanical pressure—while having a higher thermal resistance than would a bonded, brazed or soldered sensor—still provides enough thermal conductivity to allow higher EM radiation levels to be measured than can be measured by a sensor that must absorb all of the radiation entering it.

The means of applying mechanical pressure should be arranged to allow the sensor and heat sink to expand and contract, such that mechanical stresses created within the sensor over the sensor's operating temperature range do not cause the sensor to crack or break. One way in which this could be accomplished is with the use of one or more spring mechanisms which provide a spring-loaded coupling between the sensor and heat sink.

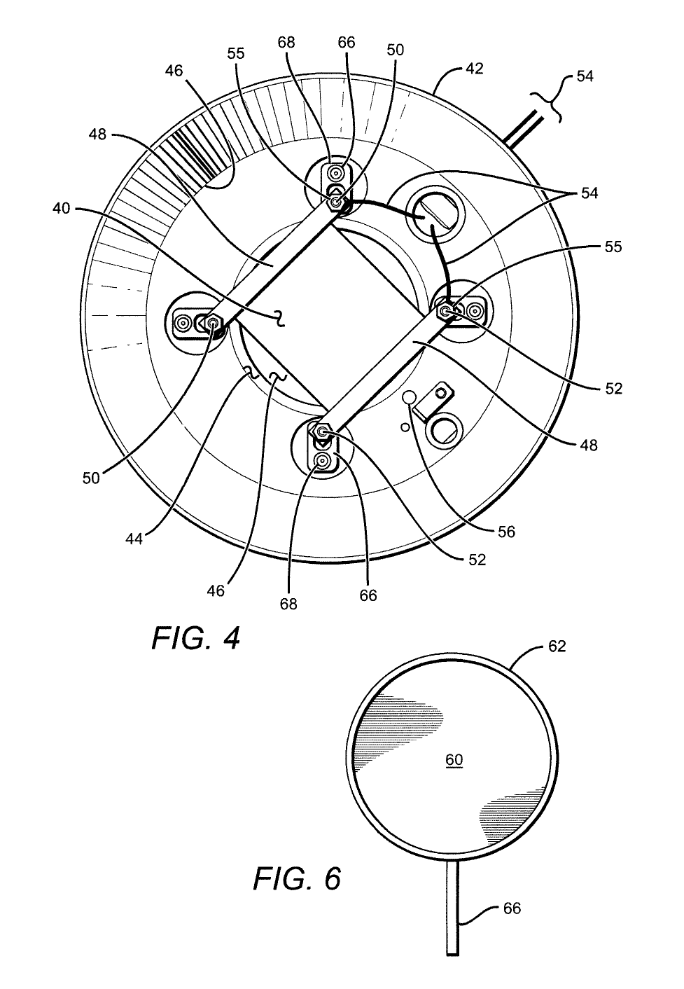

A front view of a sensor head illustrating one possible mounting arrangement is shown in FIG. 4. Here, the sensor 40 is square-shaped, and heat sink 42 includes a recessed portion 44 into which sensor 40 is arranged to fit. When arranged as shown, sensor 40 is centered over through-hole 46 when installed in recessed portion 44; through-hole 46 is chamfered in this example.

Two bars 48 extend along opposite edges of sensor 40 and between respective pairs of mounting posts 50, 52, and apply mechanical pressure which holds the sensor against the heat sink. The bars may be conductive or non-conductive, depending on the sensor type. For example, if the sensor has electrical contacts along its edges beneath bars 48, the bars can be conductive and used to connect the sensor contacts to the mounting posts. The sensor signals can then be carried away from the heat sink via electrical lead-wires 54 connected to the mounting posts with nuts 55. An exemplary device 56 that might be used to sense the temperature of heat sink 42, such as a thermocouple (TC) or resistance temperature detector (RTD), is also shown in FIG. 4.

Other means of applying mechanical pressure include, but are not limited to:
electrical contacts that apply mechanical force to sensor contacts via tension in a bent metal strip;
electrical contacts that apply mechanical force to sensor contacts via springy forces applied to a cantilever arm;
contacts that apply mechanical force to any or all portions of the rim of a sensor, but do not function as electrical contacts;
spring-loaded probes that rest directly on a sensor's contacts to provide connection to the contacts and to hold the sensor in position.

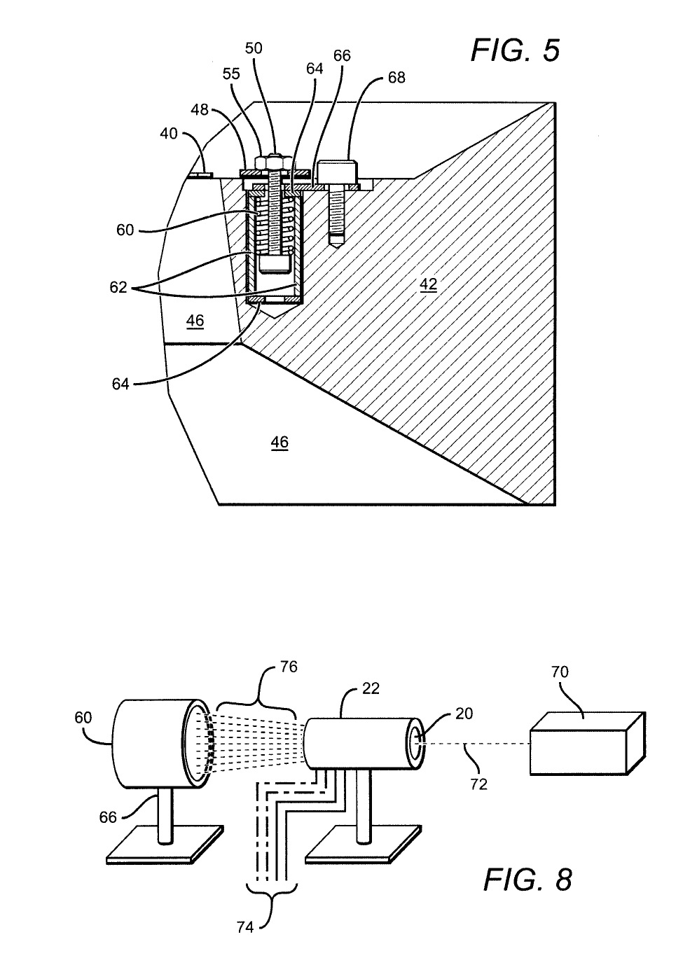

A sectional view of a spring-loading mechanism as might be used with mounting posts 50, 52 and nuts 55 is shown in FIG. 5. Here, a spring 60 is arranged to apply downward pressure on nut 55 and thus on the mounting bar 48 holding sensor 40 in place. Post 50 is preferably electrically isolated from heat sink 42 by an electrically insulating tube 62 recessed into the heat sink and positioned between two electrically insulating washers 64. The spring-loading assembly is held in place with a clip 66 that is in contact with the uppermost electrically insulating washer 64 and is secured to the heat sink with a screw 68.

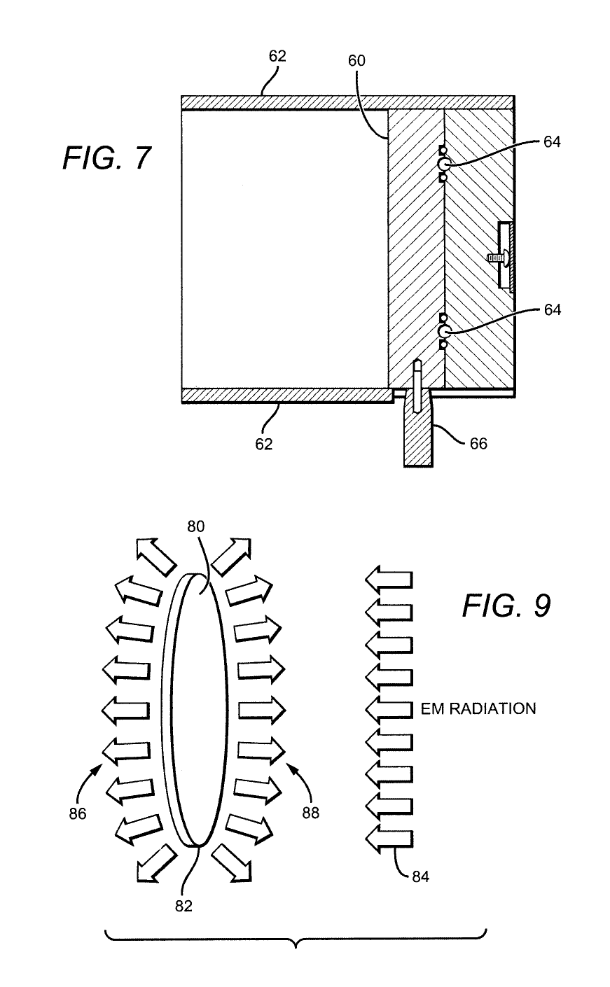

The present PE meter can also include a capture head, which would typically be mounted behind and physically separate from the sensor head, and arranged to absorb at least some of the EM radiation which is not absorbed by the sensor and which passes through the heat sink without being absorbed. The capture head may include a shroud, arranged to absorb EM radiation that does not arrive from a perpendicular direction. A front view of a capture head 60 and shroud 62 is shown in FIG. 6, and sectional and perspective views are shown in FIGS. 7 and 8.

The capture head may be any metal, but thermally conductive metals such as aluminum or copper are preferred. The shroud, which can be attached to the perimeter of the capture head as shown in FIGS. 6-8, or be self-standing and positioned between the capture head and sensor head, should also be a thermally conductive metal like aluminum or copper.

Capture head 60 comprises an absorbing surface which absorbs at least some of said EM radiation which is not absorbed by the sensor and which passes through the heat sink without being absorbed. The absorbing surface is preferably roughened to provide more absorbing surface area, and to scatter incoming EM radiation in a more dispersive manner than would a flat surface; a roughness average of greater than or equal to 12 micro-inches is preferred. The capture head's absorbing surface is also preferably black to maximize EM radiation absorption. The black surface can be created by numerous techniques, such as anodizing, painting, or evaporation.

The shroud, if present, also includes an absorbing surface. As with the capture head, the absorbing surface of the shroud is preferably roughened, preferably with a roughness average of greater than or equal to 12 micro-inches, and is black.

As shown in FIG. 7, a cooling means may be provided for capture head 60. A cooling means (not shown) might also be provided for shroud 62, whether attached to or separate from capture head 60. In the example shown, piping 64 is routed along the head which carries a liquid coolant. The capture head and/or shroud might also be kept cool via convective or fan cooling. Some or all of a supporting stand 66 is also shown in FIGS. 6-8.

FIG. 8 depicts a typical arrangement for using the present PE meter. Here, a laser 70 outputs directed EM radiation 72. The sensor head, including sensor 20 and heat sink 22, is positioned to receive and measure radiation 72 and produce signals 74 which vary with the radiation impinging on the sensor head. EM radiation (76) which is not absorbed by sensor 20 exits the sensor head via the hole through heat sink 22. Capture head 60 and shroud 62 are positioned to capture EM radiation 76.

One or both surfaces of the EM radiation sensor may be roughened, to disperse EM radiation that is reflected and/or radiation that is not absorbed. For example, in the example shown in FIG. 9, the surface 80 of sensor 82 facing the incoming EM radiation 84 is roughened. This spreads the radiation over a larger area, thus reducing the heat dissipation demands on sensor 82. In this example, the incoming EM radiation which is not absorbed by sensor 82 is equal to the radiation (86) that exits from the opposite side of the sensor plus the radiation (88) which is reflected by the sensor. By roughening surface 80, the un-absorbed radiation is dispersed over a wide area, thereby reducing the intensity of both radiation 86 and radiation 88. Roughening one or both sensor surfaces may disperse the radiation so much that a capture head or capture head and shroud may not be required.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

We claim:

1. A power and energy (PE) meter for sensing electromagnetic (EM) radiation, comprising:
a sensor head, comprising:
a sensor which absorbs EM radiation that impinges on said sensor; and
a heat sink with which said sensor is in thermal contact, said heat sink including a through-hole located behind said sensor which allows at least some of the EM radiation which is not absorbed by said sensor to pass through said heat sink without being absorbed.

2. The PE meter of claim 1, wherein said EM radiation is generated by one or more light-emitting diodes (LEDs).

3. The PE meter of claim 1, wherein said EM radiation is directed EM radiation.

4. The PE meter of claim 3, wherein said directed said EM radiation is generated by a laser.

5. The PE meter of claim 3, wherein said meter is arranged to measure the power present within a cross-sectional area of the directed EM radiation beam.

6. The PE meter of claim 3, wherein said meter is arranged to measure the energy profile/distribution for a cross-sectional area of the directed EM radiation beam.

7. The PE meter of claim 1, wherein said sensor comprises:
an absorber which is heated by EM radiation that impinges on said absorber; and
a temperature measurement device arranged to produce an output which varies with the temperature of said absorber.

8. The PE meter of claim 7, wherein said temperature measurement device is a calorimeter, pyroelectric, thermopile, bolometer, thermistor, resistance temperature device (RTD) or thermocouple.

9. The PE meter of claim 1, wherein said sensor is arranged to produce an electrical output signal which varies with the amount of EM radiation that impinges on said sensor.

10. The PE meter of claim 9, wherein said sensor comprises a one or more photodiodes or photoconductors.

11. The PE meter of claim 1, wherein said heat sink's through-hole is chamfered so as to reduce direct absorption by said heat sink of EM radiation that has passed completely through said sensor.

12. The PE meter of claim 1, wherein said heat sink comprises metal.

13. The PE meter of claim 12, wherein said heat sink comprises aluminum, copper or steel.

14. The PE meter of claim 1, further comprising a means of applying mechanical pressure which holds said sensor in thermal contact with said heat sink.

15. The PE meter of claim 14, wherein said means comprises one or more spring mechanisms.

16. The PE meter of claim 14, wherein said sensor has an associated operating temperature range, said means of applying mechanical pressure arranged to allow said sensor and heat sink to expand and contract such that mechanical stresses created within the sensor over said operating temperature range do not cause the sensor to crack or break.

17. The PE meter of claim 1, wherein said heat sink includes a recessed portion and said sensor is arranged to fit within said recessed portion.

18. The PE meter of claim 17, wherein said recessed portion and sensor are arranged such that said sensor is centered over said through-hole when installed in said recessed portion.

19. The PE meter of claim 1, further comprising a capture head mounted behind and physically separate from said sensor head, said capture head arranged to absorb at least some of said EM radiation which is not absorbed by said sensor and which passes through said heat sink without being absorbed.

20. The PE meter of claim 19, wherein said capture head comprises a thermally conductive metal.

21. The PE meter of claim 19, wherein said capture head includes an absorbing surface which absorbs at least some of said EM radiation which is not absorbed by said sensor and which passes through said heat sink without being absorbed, wherein said absorbing surface is roughened.

22. The PE meter of claim 21, wherein the roughness of said absorbing surface is greater than or equal to 12 micro-inches.

23. The PE meter of claim 19, wherein said capture head includes an absorbing surface which absorbs at least some of said EM radiation which is not absorbed by said sensor and which passes through said heat sink without being absorbed, wherein said absorbing surface is black.

24. The PE meter of claim 19, further comprising a cooling means by which said capture head is cooled.

25. The PE meter of claim 24, wherein said cooling means comprises convection cooling, fan cooling or liquid cooling.

26. The PE meter of claim 19, further comprising a shroud positioned between said capture head and said sensor head.

27. The PE meter of claim 26, wherein said shroud surrounds and extends from said capture head towards said sensor head.

28. The PE meter of claim 26, wherein said shroud comprises a thermally conductive metal.

29. The PE meter of claim 26, wherein said shroud includes an absorbing surface which absorbs at least some of said EM radiation which is not absorbed by said sensor and which passes through said heat sink without being absorbed, wherein said absorbing surface is roughened.

30. The PE meter of claim 29, wherein the roughness of said absorbing surface is greater than or equal to 12 micro-inches.

31. The PE meter of claim 26, wherein said shroud includes an absorbing surface which absorbs at least some of said EM radiation which is not absorbed by said sensor and which passes through said heat sink without being absorbed, wherein said absorbing surface is black.

32. The PE meter of claim 26, further comprising a cooling means by which said shroud is cooled.

33. The PE meter of claim 32, wherein said cooling means comprises convection cooling, fan cooling or liquid cooling.

34. The PE meter of claim 26, wherein said shroud is self-standing.

35. A power and energy (PE) meter for sensing directed electromagnetic (EM) radiation, comprising:
a sensor head, comprising:
a sensor, comprising:
an absorber which is heated by EM radiation that impinges on said absorber; and
a temperature measurement device arranged to produce an output which varies with the temperature of said absorber; and
a metal heat sink with which said sensor is in thermal contact, said heat sink including a through-hole located behind said heat sensor which allows at least some of the EM radiation which is not absorbed by said sensor to pass through said heat sink without being absorbed;
a means of applying mechanical pressure which holds said sensor in thermal contact with said heat sink; and
a capture head mounted behind and physically separate from said sensor head, said capture head comprising an absorbing surface which absorbs at least some of said EM radiation which is not absorbed by said sensor and which passes through said heat sink without being absorbed.

36. The PE meter of claim 35, wherein said heat sink's through-hole is chamfered so as to reduce direct absorption by said heat sink of EM radiation that has passed completely through said sensor.
